(19) United States
(12) Patent Application Publication
(10) Pub. No.: US 2026/0229922 A1
(43) Pub. Date: Aug. 6, 2026

(54) MODULAR WIRELESS POWER SOURCE CONSISTING OF INJECTION-LOCKED RF GENERATORS

(71) Applicant: Etherdyne Technologies, Inc., Palo Alto, CA (US)

(72) Inventors: Robert A. Moffatt, Palo Alto, CA (US); Goran Popovic, Sunnyvale, CA (US)

(21) Appl. No.: 19/159,602

(22) PCT Filed: Feb. 22, 2024
(86) PCT No.: PCT/US2024/016911

§ 371 Date: Aug. 25, 2025

Related U.S. Application Data
(60) Provisional application No. 63/486,957, filed on Feb. 24, 2023.

(51) Int. Cl. H02J 50/12; H02J 50/40; H03F 3/24

(52) U.S. Cl. CPC H02J 50/12; H02J 50/40; H03F 3/245

(57) ABSTRACT

A wireless power system includes a magnetic resonance wireless power source with multiple coupled LC resonators, each driven by a separate radiofrequency (RF) generator. The system is modular, allowing resonators to be added, subtracted, or relocated. Each RF generator is configured to sense the phases of other RF generators and adjust its phase to maintain a constant phase difference. Each RF generator includes a Class-E amplifier driven by an injection-locked oscillator and a low-pass filter outputting a current sine-wave. The RF generator senses the phase of the RF current of other RF generators through an induced voltage and adjusts its phase based on a summed voltage derived from a voltage signal and a current signal. The system maintains frequency-locking in the presence of environmental detuning by adjusting a variable capacitor.

### CROSS-REFERENCE TO RELATED APPLICATION

This application claims the benefit of and priority to U.S. Provisional Patent Application No. 63/486,957 entitled “A MODULAR WIRELESS POWER SOURCE CONSISTING OF INJECTION-LOCKED RF GENERATORS,” filed Feb. 24, 2023, the contents of which being incorporated by reference in its entirety herein.

### TECHNICAL FIELD

The present disclosure generally relates to wireless power transfer technologies and, in particular, to systems, methods, and devices for wireless power transfer using modular resonators driven by independent radiofrequency generators.

### BACKGROUND

Wireless power transfer is a technology that allows the transmission of electrical energy from a power source to an electrical load without the use of conductors or wires. This technology is based on the principle of electromagnetic induction, where a current flowing through a coil of wire generates a magnetic field, which can induce a voltage in a nearby coil. This induced voltage can then be used to power an electrical device.

One type of wireless power transfer system uses magnetic resonance, which involves the use of resonant circuits. These circuits includes inductors and capacitors, often referred to as LC resonators. The resonant frequency of these circuits is determined by the values of the inductors and capacitors.

### BRIEF SUMMARY

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

According to an aspect of the present disclosure, a wireless power system includes a magnetic resonance wireless power source having a plurality of coupled LC resonators. Each resonator is driven by a separate radiofrequency (RF) generator. Each RF generator is configured to sense phases of other RF generators and adjust its phase to maintain a constant phase difference between itself and the other RF generators. The system is modular such that each resonator may be added, subtracted, or moved to a different location.

According to other aspects of the present disclosure, the wireless power system may include one or more of the following features. Each RF generator may include a Class-E amplifier driven by an injection-locked oscillator. Each RF generator may further include a low-pass filter configured to output a current sine-wave of approximately constant amplitude. Each RF generator may be configured to sense the phase of the RF current of the other RF generators through an induced voltage sensed by the low-pass filter. Each RF generator may include a variable capacitor controlled to maintain a consistent reactance at the output terminals of the RF generator.

Each RF generator may be configured to adjust its phase based on a summed voltage derived from a voltage signal and a current signal, the voltage signal and the current signal being multiplied by respective gain factors. Each RF generator may be configured to maintain frequency-locking in the presence of environmental detuning by adjusting the variable capacitor. According to another aspect of the present disclosure, a wireless power system includes a plurality of radiofrequency (RF) generators, each RF generator connected to a separate LC resonator in a magnetic resonance wireless power source.

Each RF generator is configured to sense the RF current of other RF generators through mutual inductance between the resonators and use this sensed current to frequency-lock the RF generators. The system is modular such that each resonator may be added, subtracted, or moved to a different location. According to other aspects of the present disclosure, the wireless power system may include one or more of the following features. Each RF generator may include a Class-E amplifier driven by an injection-locked oscillator.

Each RF generator may further include a low-pass filter configured to output a current sine-wave of approximately constant amplitude. Each RF generator may be configured to sense the phase of the RF current of the other RF generators through an induced voltage sensed by the low-pass filter. Each RF generator may include a variable capacitor controlled to maintain a consistent reactance at the output terminals of the RF generator.

Each RF generator may be configured to adjust its phase based on a summed voltage derived from a voltage signal and a current signal, the voltage signal and the current signal being multiplied by respective gain factors. Each RF generator may be configured to maintain frequency-locking in the presence of environmental detuning by adjusting the variable capacitor.

The foregoing general description of the illustrative embodiments and the following detailed description thereof are merely exemplary aspects of the teachings of this disclosure and are not restrictive.

### BRIEF DESCRIPTION OF THE DRAWINGS

Many aspects of the present disclosure can be better understood with reference to the following drawings. The components in the drawings are not necessarily to scale, with emphasis instead being placed upon clearly illustrating the principles of the disclosure. Moreover, in the drawings, like reference numerals designate corresponding parts throughout the several views.

FIG. 1 is a schematic diagram of a modular wireless power system comprising multiple RF generators with coupled resonant magnetic loop antennas, according to aspects of the present disclosure.

FIG. 2 illustrates a schematic diagram of an RF generator in the modular wireless power system, featuring an injection-locked Class-E configuration, according to aspects of the present disclosure.

FIG. 3 depicts an impedance-mirroring low-pass filter configuration used in the RF generator, according to aspects of the present disclosure.

FIG. 4 presents a simplified schematic of an injection-locked oscillator circuit used in the RF generator, according to aspects of the present disclosure.

FIG. 5 shows a graph plotting phase shift against frequency deviation for the injection-locked oscillator, according to aspects of the present disclosure.

FIG. 6 displays a graph plotting DC power against frequency deviation for the RF generators, according to aspects of the present disclosure.

FIG. 7 is a photograph of an experimental setup for the modular wireless power system, demonstrating wireless power transfer to an LED load, according to aspects of the present disclosure.

FIG. 8 depicts a photograph of an experimental setup with two driven resonators in the modular wireless power system, each resonator wirelessly coupled to an LED load, according to aspects of the present disclosure.

FIG. 9 presents a set of graphs illustrating the performance characteristics of the modular wireless power system in terms of DC power draw and phase difference, according to aspects of the present disclosure.

FIG. 10 depicts a graph representing the power transfer as a function of the phase difference between two resonators in the modular wireless power system, according to aspects of the present disclosure.

### DETAILED DESCRIPTION

The present disclosure relates to systems, methods, and devices that facilitate wireless power transfer through modular resonators driven by injection-locked radiofrequency (RF) generators. In some applications, it is desirable to have a wireless power system that is adaptable to varying environments and geometries. This may be achieved using modular wireless power sources. The related art included designs for magnetic resonance wireless power systems employing modular autotuned repeaters which could be coupled together to extend the wireless power zone of a driven resonator. However, some systems of the relates art had maximum deliverable power in stable operation diminished as the number of repeaters was increased. This limitation might be avoided if each module contained its own RF power source. For maximum flexibility, it is desirable that each module contain an independent RF generator so that each module requires only DC power and no external RF connections.

To prevent a beat frequency in the power delivered to receivers which couple to multiple resonators, the RF generators must be frequency-locked. In the related art, a wireless power source consisted of a single near-field magnetic loop antenna containing multiple series-connected RF generators. The RF current in the loop was used as a common signal to injection-lock the RF generators and ensure they all operated at the same frequency and phase. The case where the RF generators are connected to separate resonators presents a different problem. In that case, the systems do not share a common signal to which they may injection lock, as there is no direct connection between them. Thus, various embodiments are described herein which allow each resonator to sense the RF current of the others through their mutual inductance, and this signal is used to frequency-lock the RF generators.

Accordingly, various embodiments are described for modular wireless power sources, where each module contains a respective radiofrequency (RF) generator. However, to prevent interference between the modules, it is often desirable for the RF generators to be frequency-locked, meaning they operate at the same frequency. Thus, the RF generators described herein can be frequency-locked to prevent interference, as will be described in greater detail below.

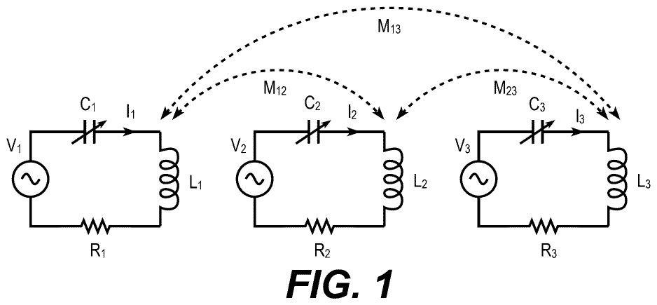

Turning now to the drawings, FIG. 1 is a schematic diagram of a modular wireless power system. The system may include a plurality of radiofrequency (RF) generators, each connected to a separate LC resonator in a magnetic resonance wireless power source. In some aspects, the first resonator may include a voltage source VI, a capacitor CI, an inductor L1, a resistor R1, and a current Il flowing therethrough. Similarly, the second resonator may include a voltage source V2, a capacitor C2, an inductor L2, a resistor R2, and a current 12. The second resonator may be coupled to the first resonator through a mutual inductance M12. The third resonator may be composed of a voltage source V3, a capacitor C3, an inductor L3, a resistor R3, and a current I3. The third resonator may have mutual inductances M13 and M23 with the first and second resonators, respectively.

In various embodiments, the mutual inductances M12, M13, and M23 may signify the wireless coupling between the resonators, allowing for the transfer of power and phase information. This transfer may be used to frequency-lock the RF generators associated with each resonator. Each RF generator may be configured to sense the RF current of other RF generators through the mutual inductance between the resonators and use this sensed current to frequency-lock the RF generators.

The system may be modular, such that each resonator may be added, subtracted, or moved to a different location, meaning that the system may include other resonators other than those depicted (e.g., a fourth resonator, a fifth resonator, and so forth). This modularity may provide flexibility in adapting the wireless power zone to varying environments and geometries, especially in context of variable-sized and dimensions wireless power transfer areas. In some aspects, the RF generators may automatically adjust the resonator tuning to accommodate variations in their mutual coupling, and the RF generators may automatically frequency-lock to prevent a beat frequency in the power delivered to receivers which couple to multiple resonators.

The addition, subtraction, or movement of a resonator can cause changes in the mutual inductance, Mₙₘ, between pairs of resonators. In order to accommodate this variation, in some embodiments, the capacitors, Cₙ, are variable and are controlled such that each RF generator sees a consistent reactance at its output terminals. Let it be assumed that each RF generator is connected to a DC power source, but has no direct RF connections to any external source. In order for the RF generators to be frequency-locked, each RF generator may be configured to sense the phases of the other generators, and adjust its phase to maintain a constant phase difference between itself and the others.

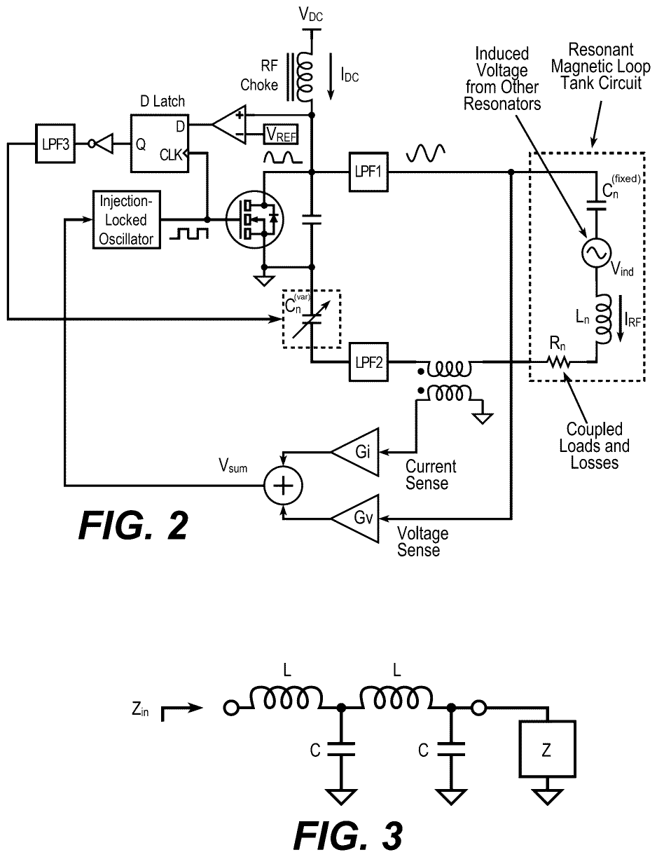

Turning now to FIG. 2, a schematic diagram of a modular wireless power system with an injection-locked Class-E RF generator is depicted. In some aspects, each RF generator in the system may include a Class-E amplifier driven by an injection-locked oscillator. The Class-E amplifier may be configured to convert a DC input into an AC output at a desired frequency, while the injection-locked oscillator may be configured to generate a stable frequency signal that can be adjusted based on an input signal.

In various embodiments, each RF generator may further include a low-pass filter, such as first low-pass filter LPF1, second low-pass filter LPF2, or third low-pass filter LPF3, configured to output a current sine-wave of approximately constant amplitude. The low-pass filter may be designed to allow frequencies below a cutoff frequency to pass through while attenuating frequencies above the cutoff frequency, thereby removing harmonics. This may help in reducing noise and interference in the output signal of the RF generator.

In some embodiments, each RF generator may be configured to sense the phase of the RF current of the other RF generators through an induced voltage sensed by the low-pass filter. For instance, the first resonator current Il, second resonator current 12, or third resonator current 13 may be sensed through their respective low-pass filters. This sensed current may be used to adjust the phase of the RF generator, thereby enabling frequency-locking among the RF generators.

In some aspects, each RF generator may include a variable capacitor, such as first resonator capacitor C1, second resonator capacitor C2, or third resonator capacitor C3, controlled or otherwise configured to maintain a consistent reactance at the output terminals of the RF generator. The variable capacitor may be adjusted based on the sensed phase of the RF current, thereby allowing the RF generator to maintain a consistent reactance despite changes in the mutual coupling between the resonators.

In various embodiments, each RF generator may be configured to adjust its phase based on a summed voltage derived from a voltage signal and a current signal, where the voltage signal and the current signal can be multiplied by respective gain factors in some implementations. This summed voltage may be used as an input to the injection-locked oscillator, thereby enabling the RF generator to adjust its phase and maintain frequency-locking with the other RF generators.

In some embodiments, each RF generator may be configured to maintain frequency-locking in the presence of environmental detuning by adjusting the variable capacitor. This may allow the RF generators to maintain a stable frequency despite changes in the environment, such as changes in temperature, humidity, or the presence of interfering signals.

FIG. 3 shows an impedance-mirroring low-pass filter configuration with inductors L and capacitors C, configured to match the input impedance Zin to the output impedance Z. This configuration may be used in the low-pass filters of the RF generators to ensure that the impedance of the input signal matches the impedance of the output signal, thereby maximizing power transfer and minimizing signal distortion.

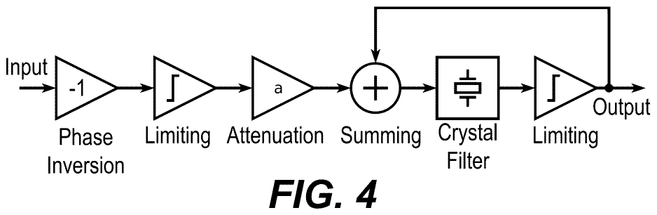

Referring now to FIG. 4, a simplified schematic of an injection-locked oscillator circuit is depicted. In some aspects, the injection-locked oscillator circuit may include a phase inversion stage, a limiting stage, an attenuation stage, a summing stage, a crystal filter, and another limiting stage, arranged in a sequential manner from the input to the output of the circuit. The phase inversion stage, denoted as “−1” in FIG. 4, may be positioned at the input side of the circuit. Thus, in some embodiments, the phase inversion stage may be configured to optionally invert the phase of the input signal. This optional phase inversion can affect the phase relationship between injection-locked RF generators within the system, providing flexibility in controlling the phase alignment of the RF generators.

Following the phase inversion stage, a limiting stage may be included in the circuit. The limiting stage may be configured to limit the amplitude of the input signal to a predetermined level, thereby preventing signal distortion or damage to subsequent stages of the circuit due to excessively high signal amplitudes. In some embodiments, the limiting stage may convert sine waves to square waves, facilitating further signal processing in the circuit.

Next in the circuit, an attenuation stage may be present, marked with the letter “a” in FIG. 4. The attenuation stage may be configured to reduce the amplitude of the signal from the limiting stage by a predetermined factor. This attenuation can help in controlling the signal power within the circuit, preventing signal overload, and ensuring stable operation of the circuit.

Following the attenuation stage, a summing stage may be included in the circuit. The summing stage may be configured to combine multiple input signals into a single output signal. This can be useful in cases where the RF generator is designed to sense and adjust its phase based on multiple input signals, such as a voltage signal and a current signal.

Subsequent to the summing stage, a crystal filter may be included in the circuit. The crystal filter may be configured to filter out unwanted frequencies from the summed signal, allowing a signal of a desired frequency or desired range of frequency to pass through. This can help in maintaining the frequency stability of the RF generator, ensuring that it operates at the desired frequency despite variations in the input signals or environmental conditions.

Finally, another limiting stage may be positioned at the output side of the circuit. Similar to the first limiting stage, this limiting stage may limit the amplitude of the output signal to a predetermined level, ensuring that the output signal of the injection-locked oscillator circuit is within a desired amplitude range. In various embodiments, this limiting stage may also convert sine waves to square waves, providing a square wave output signal from the injection-locked oscillator circuit.

In some embodiments, the injection-locked oscillator circuit may be part of an RF generator in a modular wireless power system, as described above. The injection-locked oscillator circuit may be configured to generate a stable frequency signal that can be adjusted based on an input signal, such as a summed voltage derived from a voltage signal and a current signal. This can enable the RF generator to adjust its phase and maintain frequency-locking with other RF generators in the system, facilitating efficient and stable wireless power transfer in the system.

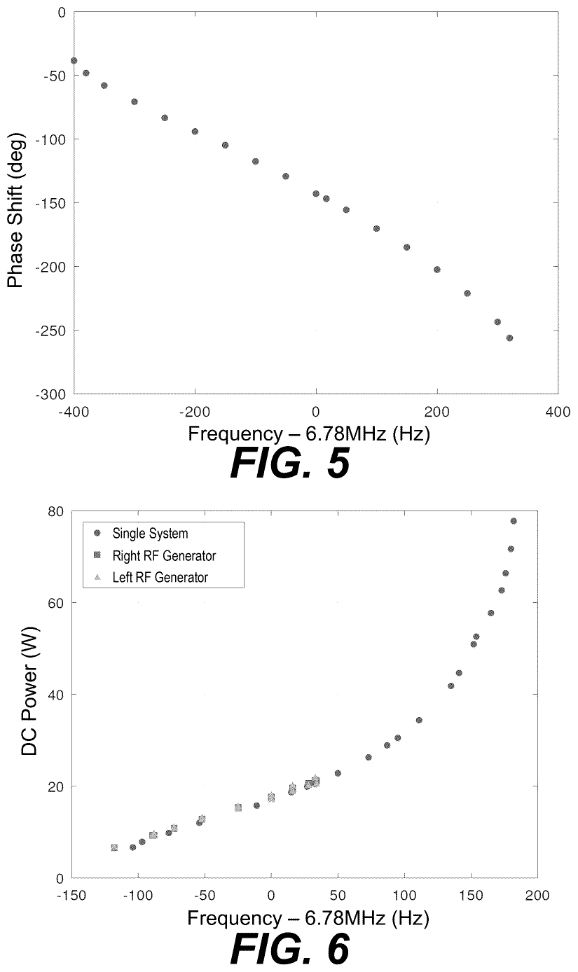

Turning now to FIGS. 5-6, a set of graphs related to a modular wireless power system with injection-locked RF generators is depicted. FIG. 5 displays a graph plotting phase shift in degrees against frequency deviation from a central frequency of 6.78 MHz. This graph may illustrate the phase response characteristics of the injection-locked oscillator in some aspects. The phase shift may represent the difference in phase between the input and output of the injection-locked oscillator. The frequency deviation may represent the difference between the actual operating frequency of the oscillator and the central frequency of 6.78 MHz. The graph may demonstrate the operational performance of the RF generators in terms of phase stability across a range of frequencies.

In various embodiments, the phase shift may vary linearly with frequency deviation, indicating a linear phase response of the injection-locked oscillator. In some embodiments, the phase shift may vary non-linearly with frequency deviation, indicating a non-linear phase response of the injection-locked oscillator. The specific relationship between phase shift and frequency deviation may depend on various factors, such as the design of the injection-locked oscillator, the operating conditions of the RF generators, and the mutual coupling between the resonators.

FIG. 6 shows a graph plotting DC power in watts against frequency deviation from the same central frequency of 6.78 MHz. This graph may compare the power characteristics of a single system with those of the right and left RF generators within the modular system. The DC power may represent the power consumed by the RF generators, while the frequency deviation may represent the difference between the actual operating frequency of the RF generators and the central frequency of 6.78 MHz. The graph may demonstrate the operational performance of the RF generators in terms of power consumption across a range of frequencies.

In some aspects, the DC power may increase with increasing frequency deviation, indicating a positive correlation between power consumption and frequency deviation. In other aspects, the DC power may decrease with increasing frequency deviation, indicating a negative correlation between power consumption and frequency deviation. The specific relationship between DC power and frequency deviation may depend on various factors, such as the design of the RF generators, the operating conditions of the RF generators, and the mutual coupling between the resonators.

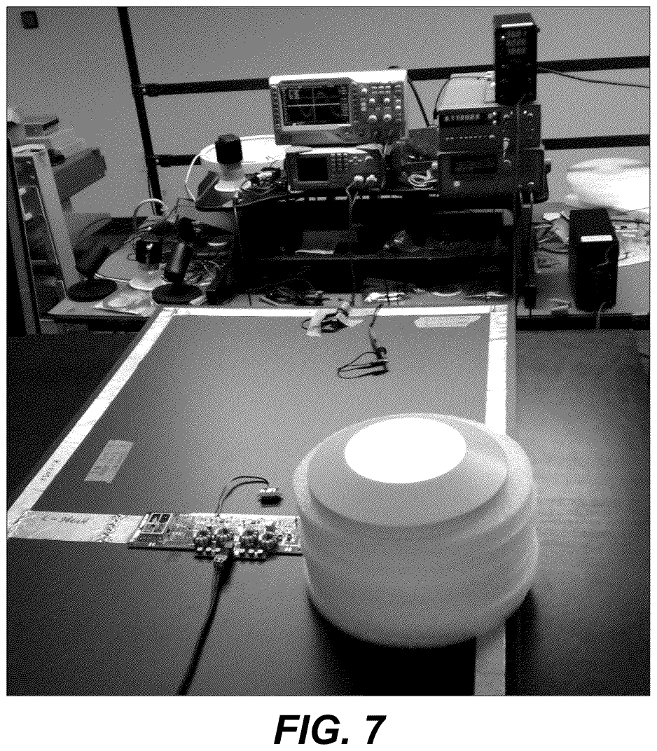

Referring now to FIG. 7, a photograph of an experimental setup for a modular wireless power system with injection-locked RF generators is depicted. The setup may include various electronic equipment such as an oscilloscope, a function generator, and other measurement devices on a workbench. In some aspects, the setup may be located in a laboratory environment where the system is being tested and analyzed.

In the foreground of the photograph, a resonator with an attached circuit board is visible. The resonator may be one of the resonators in the modular wireless power system, such as the first resonator, the second resonator, or the third resonator. The resonator may be connected to an RF generator, which may be configured to drive the resonator at a desired frequency. The RF generator may include various components such as a Class-E amplifier, an injection-locked oscillator, and a low-pass filter, as described above.

In various embodiments, a wireless LED load may be positioned to the right of the resonator in the photograph. The LED load may represent a device that receives power wirelessly from the resonator. The LED load may be coupled to the resonator through a magnetic field generated by the resonator, allowing for wireless power transfer from the resonator to the LED load. The LED load may include one or more LEDs that light up when they receive power from the resonator, demonstrating the wireless power transfer capability of the system.

The resonator and the LED load may showcase the practical application of the described system in a real-world environment. In some aspects, the resonator and the LED load may be movable, allowing for the configuration of the wireless power zone to be easily adapted to varying environments and geometries. This may provide flexibility in the placement of the resonator and the LED load, facilitating efficient and convenient wireless power transfer in various application scenarios.

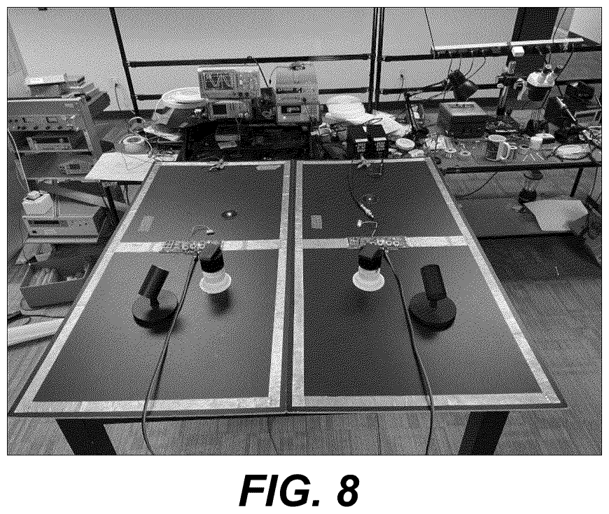

Referring now to FIG. 8, a photograph of an experimental setup for a modular wireless power system with injection-locked RF generators is depicted. In some aspects, the system may include two separate resonators, each with associated circuitry, placed in a specific arrangement. Each resonator, which may be the first resonator, the second resonator, or the third resonator as described earlier, may be wirelessly coupled to an LED load. The LED load may be indicated by the illuminated LEDs in the photograph, demonstrating the wireless power transfer capability of the system.

In various embodiments, the resonators may be connected to power sources via cables, such as red cables as shown in the photograph. The cables may provide DC power to the RF generators associated with each resonator, enabling the RF generators to generate the RF signals that drive the resonators. The power sources may be any suitable power sources capable of providing the requisite DC power, such as batteries, power adapters, or power supply units.

The experimental setup may also include various electronic equipment and tools, as can be seen in the background of the photograph. This may indicate that the system is being tested and analyzed in a laboratory environment. The electronic equipment may include devices such as oscilloscopes, function generators, frequency counters, and other measurement devices, which may be used to monitor and analyze the performance of the system.

In some aspects, the resonators and the LED loads may be movable, allowing for the configuration of the wireless power zone to be easily adapted to varying environments and geometries. This may provide flexibility in the placement of the resonators and the LED loads, facilitating efficient and convenient wireless power transfer in various application scenarios. For instance, the resonators may be moved closer together or further apart to adjust the mutual inductance between them, thereby affecting the frequency-locking of the RF generators. Similarly, the LED loads may be moved closer to or further from the resonators to adjust the power received by the loads.

In various embodiments, the resonators may be added, subtracted, or moved to different locations within the wireless power zone, as described earlier. This may allow for the creation of a wireless power zone that can be adapted to varying environments and geometries, providing maximum flexibility in the deployment of the system. For example, additional resonators may be added to extend the wireless power zone, or existing resonators may be moved to different locations to adapt the wireless power zone to a new environment or geometry.

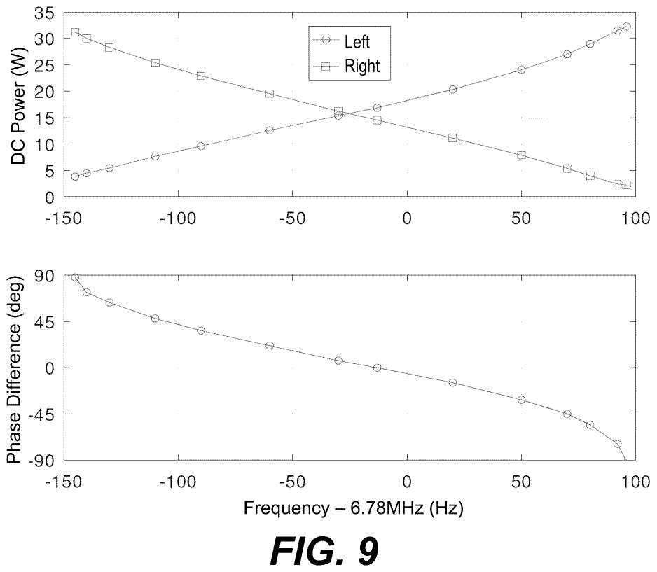

Turning now to FIG. 9, a set of graphs illustrating the performance characteristics of a modular wireless power system with injection-locked RF generators is depicted. The top graph may display the DC power draw of the left and right RF generators as a function of frequency deviation from a central frequency of 6.78 MHz. In some aspects, the left RF generator may be represented by circles and the right RF generator by squares. This graph may demonstrate the relationship between frequency deviation and DC power consumption, which are both pivotal parameters for maintaining stable and efficient wireless power transfer in the system.

In various embodiments, the DC power draw of the RF generators may increase with increasing frequency deviation, indicating a positive correlation between power consumption and frequency deviation. In some embodiments, the DC power draw of the RF generators may decrease with increasing frequency deviation, indicating a negative correlation between power consumption and frequency deviation. The specific relationship between DC power and frequency deviation may depend on various factors, such as the design of the RF generators, the operating conditions of the RF generators, and the mutual coupling between the resonators.

The bottom graph in FIG. 9 may show the phase difference between the RF generators over the same frequency range. This graph may indicate the phase locking behavior of the system. In some aspects, the phase difference between the RF generators may remain constant over the frequency range, indicating that the RF generators are frequency-locked. In some embodiments, the phase difference between the RF generators may vary over the frequency range, indicating that the RF generators are adjusting their phases to maintain frequency-locking.

In some embodiments, the system may be able to maintain frequency lock as long as the difference in loading between the two sides is less than approximately 28 W. This may imply that the system can tolerate a degree of imbalance in the loading of the resonators while still maintaining frequency lock. This feature may provide flexibility in the distribution of wireless loads among the resonators, facilitating efficient and convenient wireless power transfer in various application scenarios.

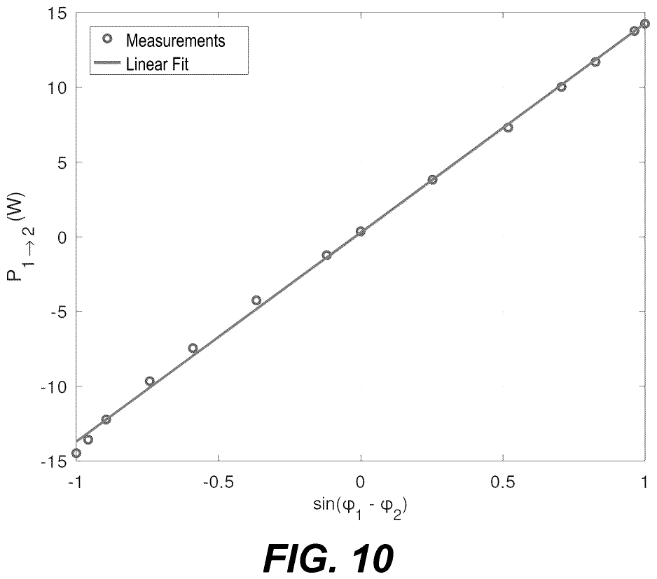

Referring now to FIG. 10, a graph representing the power transfer as a function of the phase difference between two resonators in a modular wireless power system is depicted. The horizontal axis of the graph may be labeled with the sine of the phase difference between the RF currents in the resonators, sin(φ1-φ2), and the vertical axis may represent the power transfer, P1→2, in watts (W). The graph may include data points labeled as “Measurements” which are fitted with a “Linear Fit” line, illustrating the linear relationship between the power transfer and the sine of the phase difference.

In some aspects, the power transfer between two resonators may be computed by taking the measured DC power and subtracting the DC power draw of that RF generator when the two resonators were uncoupled. The power transfer may then be computed by taking the difference between the resulting excess powers and dividing by 2. This calculation may provide a measure of the power transfer between the resonators, which may be used to maintain frequency-locking among the RF generators.

In various embodiments, the power transfer between the resonators may be directly proportional to the sine of the phase difference between the RF currents in the resonators. This may imply that the power transfer increases as the phase difference approaches 90 degrees, and decreases as the phase difference approaches 0 or 180 degrees. This relationship may provide a mechanism for the RF generators to adjust their phases to maintain a constant phase difference and hence frequency-locking, despite variations in the mutual coupling between the resonators.

In some embodiments, the system may be modular, such that each resonator may be added, subtracted, or moved to a different location. This modularity may provide flexibility in adapting the wireless power zone to varying environments and geometries. For instance, additional resonators may be added to extend the wireless power zone, or existing resonators may be moved to different locations to adapt the wireless power zone to a new environment or geometry. In such cases, each RF generator may be connected to a separate LC resonator in a magnetic resonance wireless power source, and may be configured to sense the RF current of other RF generators through mutual inductance between the resonators and use this sensed current to frequency-lock the RF generators.

The foregoing description sets forth exemplary aspects of the present disclosure. It should be recognized, however, that such description is not intended as a limitation on the scope of the present disclosure. Rather, the description also encompasses combinations and modifications to those exemplary aspects described herein. A number of implementations have been described. Nevertheless, it will be understood that various modifications may be made without departing from the spirit and scope of the disclosure. Accordingly, other implementations are within the scope of the following claims.

The features, structures, or characteristics described above may be combined in one or more embodiments in any suitable manner, and the features discussed in the various embodiments may be interchangeable, if possible. In the following description, numerous specific details are provided in order to fully understand the embodiments of the present disclosure. However, a person skilled in the art will appreciate that the technical solution of the present disclosure may be practiced without one or more of the specific details, or other methods, components, materials, and the like may be employed. In other instances, well-known structures, materials, or operations are not shown or described in detail to avoid obscuring aspects of the present disclosure.

Although the relative terms such as “on,” “below,” “upper,” and “lower” are used in the specification to describe the relative relationship of one component to another component, these terms are used in this specification for convenience only, for example, as a direction in an example shown in the drawings. It should be understood that if the device is turned upside down, the “upper” component described above will become a “lower” component. When a structure is “on” another structure, it is possible that the structure is integrally formed on another structure, or that the structure is “directly” disposed on another structure, or that the structure is “indirectly” disposed on the other structure through other structures.

In this specification, the terms such as “a,” “an,” “the,” and “said” are used to indicate the presence of one or more elements and components. The terms “comprise,” “include,” “have,” “contain,” and their variants are used to be open ended, and are meant to include additional elements, components, etc., in addition to the listed elements, components, etc. unless otherwise specified in the appended claims.

The terms “first,” “second,” etc. are used only as labels, rather than a limitation for a number of the objects. It is understood that if multiple components are shown, the components may be referred to as a “first” component, a “second” component, and so forth, to the extent applicable.

The above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

Therefore, the following is claimed:

1. A wireless power system, comprising:
a magnetic resonance wireless power source having a plurality of coupled LC resonators, each resonator driven by a separate radiofrequency (RF) generator;
wherein each RF generator is configured to sense phases of other RF generators and adjust its phase to maintain a constant phase difference between itself and the other RF generators; and
wherein the system is modular such that each resonator may be added, subtracted, or moved to a different location.

2. The wireless power system of claim 1, wherein each RF generator comprises a Class-E amplifier driven by an injection-locked oscillator.

3. The wireless power system of claim 2, wherein each RF generator further comprises a low-pass filter configured to output a current sine-wave of approximately constant amplitude.

4. The wireless power system of claim 3, wherein each RF generator is configured to sense the phase of the RF current of the other RF generators through an induced voltage sensed by the low-pass filter.

5. The wireless power system of claim 4, wherein each RF generator comprises a variable capacitor controlled to maintain a consistent reactance at the output terminals of the RF generator.

6. The wireless power system of claim 5, wherein each RF generator is configured to adjust its phase based on a summed voltage derived from a voltage signal and a current signal, the voltage signal and the current signal being multiplied by respective gain factors.

7. The wireless power system of claim 6, wherein each RF generator is configured to maintain frequency-locking in the presence of environmental detuning by adjusting the variable capacitor.

8. A wireless power system, comprising:
a plurality of radiofrequency (RF) generators, each RF generator connected to a separate LC resonator in a magnetic resonance wireless power source;
wherein each RF generator is configured to sense the RF current of other RF generators through mutual inductance between the resonators and use this sensed current to frequency-lock the RF generators.

9. The wireless power system of claim 8, wherein the system is modular such that each resonator may be added, subtracted, or moved to a different location.

10. The wireless power system of claim 8, wherein each RF generator comprises a Class-E amplifier driven by an injection-locked oscillator, and each RF generator further comprises a low-pass filter configured to output a current sine-wave of approximately constant amplitude.

11. The wireless power system of claim 10, wherein each RF generator is configured to sense the phase of the RF current of the other RF generators through an induced voltage sensed by the low-pass filter.

12. The wireless power system of claim 11, wherein each RF generator comprises a variable capacitor controlled to maintain a consistent reactance at the output terminals of the RF generator.

13. The wireless power system of claim 12, wherein each RF generator is configured to adjust its phase based on a summed voltage derived from a voltage signal and a current signal, the voltage signal and the current signal being multiplied by respective gain factors.

14. The wireless power system of claim 13, wherein each RF generator is configured to maintain frequency-locking in the presence of environmental detuning by adjusting the variable capacitor.

15. A method for forming a wireless power zone, comprising:
providing a magnetic resonance wireless power source having a plurality of coupled LC resonators, each resonator driven by a separate radiofrequency (RF) generator;
configuring each RF generator to sense phases of other RF generators and adjust its phase to maintain a constant phase difference between itself and the other RF generators; and
modifying the configuration of the wireless power zone by adding, subtracting, or moving resonators to different locations.

16. The method of claim 15, wherein each RF generator comprises a Class-E amplifier driven by an injection-locked oscillator.

17. The method of claim 16, wherein each RF generator further comprises a low-pass filter configured to output a current sine-wave of approximately constant amplitude.

18. The method of claim 17, wherein each RF generator is configured to sense the phase of the RF current of the other RF generators through an induced voltage sensed by the low-pass filter.

19. The method of claim 18, wherein each RF generator comprises a variable capacitor controlled to maintain a consistent reactance at the output terminals of the RF generator.

20. The method of claim 19, wherein each RF generator is configured to adjust its phase based on a summed voltage derived from a voltage signal and a current signal, the voltage signal and the current signal being multiplied by respective gain factors.
